(19) United States
(12) Patent Application Publication
(10) Pub. No.: US 2003/0058138 A1
(43) Pub. Date: Mar. 27, 2003

(54) Intelligent keypad scanner

(76) Inventors: Vinod Nair Gopikuttan Nair, Singapore (SG); Amit Sadashiv Shaligram, Singapore (SG); Martin Erdmann, Munich (DE)

Correspondence Address: Siemens Corporation, Intellectual Property Department, 186 Wood Avenue South, Iselin, NJ, 08830, US

(21) Appl. No.: 09/964,199

(22) Filed: Sep. 26, 2001

(51) Int. Cl. H03M 11/00; H03K 17/94

(52) U.S. Cl. 341/22; 341/26

(57) ABSTRACT

A keypad arrangement is disclosed comprising a scanning unit (30) having a certain number of port line terminals (1 to 11) and a number of sensor cells (21) arranged in half-matrix structure having rows (23) and columns (22) whereby the number of columns (22) and the number of rows (23) each are less than the number of port line terminals. In comparison to normal detection systems, the given detection system allows a significant reduction of the port line terminals required to scan a given number of sensor cells. The device described is preferably applicable in communication devices.

### BACKGROUND OF THE INVENTION

The present invention relates to a keypad arrangement and to a method of detecting.

Especially in the field of communications, many electrical devices have input units like keypads or keyboards.

In the technical field of mobile communications, main targets of current research and development include the need for smaller and lighter systems. Additionally, the need to reduce costs requires integrated circuit chips with a reduced number of pins.

Keypads of corded as well as cordless telephones and portable or cellular phones normally have the keys arranged in a matrix structure. A pushed key is thereby detected by a specific column and row number pair by which each key can be uniquely identified. The problem of this kind of keypad is, that a relatively large number of pins at a scanning unit connected to this kind of keypad is required to transmit column and line information by normally connecting all column lines and all row lines to respective cordline terminals at the keypad scanner.

### SUMMARY OF THE INVENTION

It is an object of the present invention to provide a detection system which reduces the number of necessary IC pins while supporting a large number of keys in a communication system.

According to the present invention, a detection system is provided. The detection system comprises a scanning unit with n+1 port line terminals and a plurality of sensor cells arranged in a half matrix structure defined by columns and rows. The half matrix structure has a maximum of n columns connected to port line terminals and a maximum of n rows connected to port line terminals.

In the present document, port line terminals are understood as terminals of respective lines within an I/O-Interface coupling a keypad with a control unit to control this keypad.

Due to the use of a half-matrix structure, the necessary number of port pins to support a given number of keys in a keypad can be substantially reduced. Or, with a given number of port pins, the number of supported keys of a keyboard can be increased significantly.

This is especially advantageous for use in telephone systems, especially with mobile or cellular telephones.

For example, to support 55 sensor cells or keys of the keypad, with the given detection system, only 11 port lines are needed instead of 16 port lines for prior art keypads. In general, with a number of M port lines, it is possible to couple M(M−1)/2 keys to these M port lines in a half-matrix format.

To detect an activated sensor cell, it is easily possible to scan the sensor cells with a scan procedure comprising several scan steps. For example, in a first scan step, one of the port line terminals can be used as an input terminal and be fed with a defined state. The remaining port line terminal, acting as output terminals in this case, are read out. If one of the sensor cells corresponding to these port lines is activated, this state can be scanned by reading out a logical value of the given port line. For example, if the input level is low, the corresponding sensor cell to that terminal line is activated or the corresponding key in that line is pressed.

In a next scan step, another input terminal line different from the first input line is used as an input line, all remaining lines again are used as output lines.

The detection system described significantly reduces weight and space and also costs of communication systems, especially telephones.

According to a preferred embodiment of the present invention, the scanning unit comprises a first register to store the results of a first scanning step performed by setting a first port line terminal to a defined value and reading out values of the remaining port line terminals.

Having a scanning unit with a number of n+1 port line terminals, it is preferable to have a n-bit-register, as one port line terminal is used as an input terminal. The register preferably is an internal, temporary register. For further processing of scanning information, the register might be a shift register with a serial output. The scanning information stored in the register might for example further be processed by a microcontroller.

In a further embodiment of the present invention, the scanning unit comprises a second register to store the results of a second scanning step performed by setting a second port line terminal different from the first port line terminal to a defined value and reading out values of the remaining port line terminals, and the scanning unit comprises a comparator to compare registers 1 and 2 and to send a detection signal when the information stored in the registers 1 and 2 is equal.

To compare the contents of one internal register with the contents of a second register having the previously stored value in two successive scan cycles ensures that a correct detection of an activated sensor cell is performed and that scanning detection in error due to glitches or other errors is avoided.

In a further embodiment of the present invention, the number of columns is equal to the number of rows. A symmetrical half matrix structure guarantees a high efficiency of the present detection system, as the largest possible number of sensor cells can be controlled by the lowest possible number of port line terminals of an integrated circuit.

In a further, preferred embodiment of the present invention, the number of rows is 10 and the number of columns is 10. With 10 rows and 10 columns in combination with a half matrix structure, 55 sensor cells can be controlled, which is sufficient for most communication device keypads, having for example numeric keys and additional function keys. For this purpose, only 11 port lines are required which is one port line more than the maximum of the number of rows and the number of columns.

In a further, preferred embodiment of the present invention, the scanning unit is coupled to a controlling unit to process information detected from the sensor cells. The controlling unit may be a microprocessor which might be activated by a detection system interrupt signal.

In a further embodiment of the present invention, each sensor cell includes one key of a keypad. The keypad keys may be numeric keys as known from telephones as well as additional function keys or alphanumeric keys or others.

Further advantageous features, aspects and details of the invention are evident from the dependent claims.

### BRIEF DESCRIPTION OF THE DRAWINGS

FIG. 1 shows a simplified structural diagram of a first embodiment of the present invention.

### PREFERRED EMBODIMENTS OF THE INVENTION

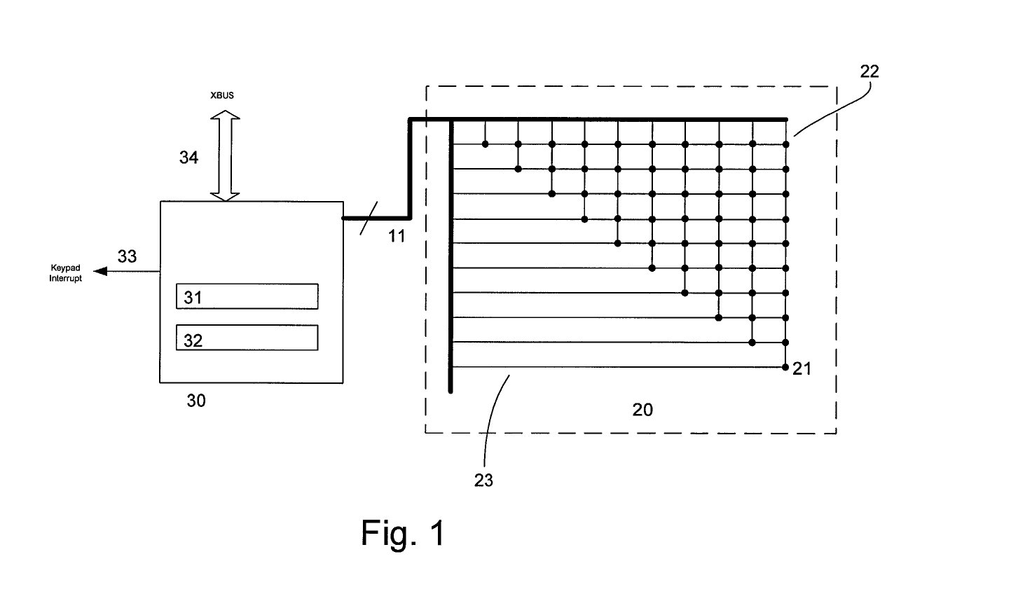

FIG. 1 shows detection system in accordance with one embodiment of the invention.

The system includes a keypad 20 having a plurality of sensor cells or keys 21. Keys 21 are arranged in a half-matrix structure defined by column lines 22 and row lines 23 and having a triangular shape. In one embodiment, the matrix structure comprises 55 sensor cells.

The keypad 20 is connected to a keypad scanning unit 30 having two temporary registers 31, 32 and also a terminal for an interrupt line 33 by which the scanning unit 30 may be connected to a microcontroller. The scanning unit 30 further has a bus interface 34 for transmission of detected input information introduced via the keypad for further processing of input data.

The keypad 20 features a 10 by 10 matrix having 10 columns 22 numbered 0 to 9 and 10 rows 23 numbered 1 to 10. The numbers or addresses of columns and rows 22, 23 at the same time are numbers or addresses 0 to 10 of 11 port line terminals of scanning unit 30 to which columns and rows 22, 23 of keypad 20 are coupled.

To form a half matrix structure, row line 1 is coupled to column line 0 via one sensor cell 21 only, row line 2 to column lines 0 and 1 via one respective sensor cell 21, row line 3 to column lines 0 to 2, and so on, row line 10 to column lines 0 to 9. With this matrix structure, a detection of an activated sensor cell or a pressed key in the half matrix structure can easily be detected using a relatively low number of port line terminals.

Here, only 11 port line terminal are required to address all 55 keys, while in a prior art matrix of for example 5 rows and 11 columns, 5+11=16 port line terminals would be required to address all keys via a pair of column and row numbers.

To scan if any key 21 of the given keypad 20 is pressed, column lines 0 to 9 are activated successively one after the other, while the remaining 10 respective port lines are scanned. For example, the scanning procedure starts with setting line 0 to 0 and reading lines 1 to 10. The last scan procedure ends with setting line 9 to 0 and reading line 10. Doing so, a logical low value indicates a line which is driven to low when using internal pull-up-transistors. This means, if the input level is low, the corresponding key in that line is pressed.

Processing the results of these multistep scan procedures is handled within the scanning unit 30 as follows: If line 0 is set to logical 0, the result of scanning lines 1 to 10, if 10 lines are enabled, otherwise less, is stored in an internal, temporary register 31. An analog procedure is performed when line 1 is set to logical 0 and so on. The content of the internal register 31 is compared with the content of the previously stored value, which is stored in register 32. That means, that with every transfer of a new scan word from keypad 20 to register 31, the previous content of register 31 is transferred to register 32 so that register 32 always contains the information of the previous scanning step. If a key is detected as pressed in two successive scan cycles, the information is transferred to a certain register using for example bus 34. A change of any of these registers causes an interrupt signal, which can then be serviced by an associated controller to interpret the keypad input.

As for the port pins of the keypad scanner an internal pull-up-transistor can be enabled, no external resistors are needed to provide a pull-up-terminal.

The described half-matrix structure in conjunction with the scan procedure described makes a substantial reduction of the necessary number of port pins of a keypad possible. The invention is preferably applicable in mobile communication systems.

It is of course possible and within the scope of the present invention to extend the device described above for larger numbers of keys supported. Instead of the keys forming a keypad, any other sensor cells forming a detecting device are within the scope of the present invention.

What is claimed is:

1. Keypad arrangement, comprising
a scanning unit with a number of n+1 port line terminals and a number of sensor cells arranged in a half matrix structure defined by columns and rows, having a maximum number of n columns connected to corresponding port line terminals and a maximum number of n rows connected to corresponding port line terminals.
